(19) United States
(12) Patent Application Publication
(10) Pub. No.: US 2026/0059878 A1
(43) Pub. Date: Feb. 26, 2026

(54) PHOTOELECTRIC PACKAGING STRUCTURE, MANUFACTURING METHOD THEREOF, AND CAMERA MODULE

(71) Applicant: TRIPLE WIN TECHNOLOGY(SHENZHEN) CO. LTD., Shenzhen (CN)

(72) Inventors: HUNG-TA LI, New Taipei (TW); Hsin-Yen Hsu, New Taipei (TW); Yi-Mou Huang, New Taipei (TW); Tzu-Li Feng, New Taipei (TW)

(21) Appl. No.: 19/249,028

(22) Filed: Jun. 25, 2025

(30) Foreign Application Priority Data
Aug. 22, 2024 (CN) 202411159138.6

(51) Int. Cl. H10F 39/00

(52) U.S. Cl. CPC H10F 39/804; H10F 39/011

(57) ABSTRACT

A photoelectric packaging structure, manufacturing method, and camera module are provided. The structure includes a substrate module, a photosensitive chip, and a cover module. The substrate module includes a packaging body and a first conductive structure. The first conductive structure includes a first and a second conductive channels, a first to a third conductive pads. The first and the second conductive channel are formed in the packaging body. The first conductive channel is connected to the first conductive pad and the second conductive pad. The photosensitive chip is located in the packaging body. The second conductive channel is connected to the non-photosensitive area and the third conductive pad. The cover module includes a cover plate body and a second conductive structure. The fourth conductive pad is connected to the second conductive pad and the third conductive pad.

### CROSS-REFERENCE TO RELATED APPLICATION

This application claims the benefit and priority to Chinese Patent Application Serial No. 202411159138.6, filed on Aug. 22, 2024, entitled “PHOTOELECTRIC PACKAGING STRUCTURE, MANUFACTURING METHOD THEREOF, AND CAMERA MODULE”, and the content of which is hereby fully incorporated by reference.

### FIELD

The subject matter herein generally relates to semiconductor packages, and more particularly, to a photoelectric packaging structure, a manufacturing method of the photoelectric packaging structure, and a camera module with the photoelectric packaging structure.

### BACKGROUND

Camera modules may include circuit boards and photosensitive chips mounted on the circuit boards. The photosensitive chip may be connected to conductive pads of the circuit board through a wire bonding technology.

However, a wire bonding tool needs a certain space between the photosensitive chip and the conductive pad of the circuit board when operated, which results in an increase in the lateral size between the photosensitive chip and the conductive pad. Furthermore, a line width and a line spacing of the circuit board are limited by process factors and difficult to be reduced, which is not conducive to the miniaturization development of the camera module. Moreover, heat treatment is involved in each of the circuit board manufacturing process and the wire bonding process, and the circuit board is easily deformed at high temperatures, which lowers the quality of the camera module. Improvements in the art are desired.

### BRIEF DESCRIPTION OF THE DRAWINGS

FIG. 1 is a block diagram of a camera module according to an embodiment of the present disclosure.

FIG. 2 is a diagrammatic view of a photoelectric packaging structure of the camera module shown in FIG. 1.

FIG. 3 is a diagrammatic view showing a photosensitive chip and an electronic component placed on a first carrier board according to an embodiment of the present disclosure.

FIG. 4 is a diagrammatic view showing a first packaging block formed on the first carrier board shown in FIG. 3.

FIG. 5A is a diagrammatic view showing the first carrier board shown in FIG. 4 removed and a wiring pattern formed at a bottom of the first packaging block.

FIG. 5B is a top view of the first packaging block, the photosensitive chip, and the electronic component shown in FIG. 5A.

FIG. 6 is a diagrammatic view showing the first packaging block shown in FIG. 5A placed on a second carrier board and a second packaging block formed on the first packaging block.

FIG. 7A is a diagrammatic view showing a hollow channel defined in the first and second packaging blocks shown in FIG. 6 and a conductive material filled in the hollow channel.

FIG. 7B is a top view of the second packaging block, the photosensitive chip, and the electronic component shown in FIG. 7A.

FIG. 8 is a diagrammatic view showing a solder paste formed on a first conductive structure shown in FIG. 7A to obtain a substrate module.

FIG. 9 is a diagrammatic view of a cover plate body with a first film layer and a second film layer according to an embodiment of the present disclosure.

FIG. 10 is a diagrammatic view showing an insulation protection layer formed on the cover plate body shown in FIG. 9.

FIG. 11A is a diagrammatic view showing a second conductive structure formed on the insulating protective layer shown in FIG. 10 to obtain a cover module.

FIG. 11B is a top view of the cover module shown in FIG. 11A.

FIG. 12 is a diagrammatic view showing the cover plate body shown in FIG. 11A mounted on the substrate module shown in the FIG. 8.

FIG. 13 is a diagrammatic view showing the cover module shown in FIG. 12 processed and a sealing material formed between the cover module and the substrate module.

FIG. 14 is a diagrammatic view of a photoelectric packaging structure according to another embodiment of the present disclosure.

FIG. 15 is a diagrammatic view of a cover plate body with a second conductive structure according to another embodiment of the present disclosure.

FIG. 16 is a diagrammatic view showing a groove defined in the cover plate body shown in FIG. 15.

FIG. 17 is a diagrammatic view showing a first film layer and a second film layer formed on the cover plate body shown in FIG. 16 to obtain a cover module.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

### First Embodiment

Referring to FIG. 1, a camera module 1 is provided according to an embodiment of the present disclosure. The camera module 1 includes a lens assembly 2 and a photoelectric packaging structure 100. The lens assembly 2 has an optical path for an external light beam to pass through. The photoelectric packaging structure 100 receives the external light beam passing through the lens assembly 2 to form an optical signal, and then converts the optical signal into electrical signal to realize photoelectric conversion.

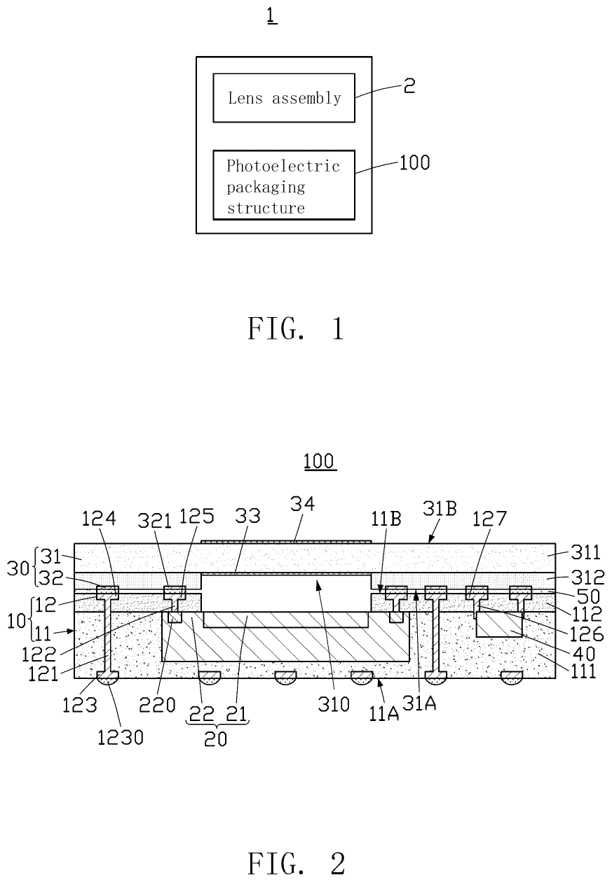

Referring to FIG. 2, the photoelectric packaging structure 100 includes a substrate module 10, a photosensitive chip 20, and a cover module 30. The substrate module 10 includes a packaging body 11 and a first conductive structure 12 formed in the packaging body 11. The packaging body 11 includes a first surface 11A and a second surface 11B opposite to each other. The first conductive structure 12 includes a first conductive channel 121, a second conductive channel 122, a first conductive pad 123, a second conductive pad 124, and a third conductive pad 125. The first conductive channel 121 and the second conductive channel 122 are formed in the packaging body 11. The first conductive pad 123 is exposed from the first surface 11A. The second conductive pad 124 and the third conductive pad 125 are exposed from the second surface 11B. Two ends of the first conductive channel 121 are connected to the first conductive pad 123 and the second conductive pad 124, respectively. One end of the second conductive channel 122 is connected to the third conductive pad 125. In some embodiment, a solder ball 1230 may be provided on the first conductive pad 123, and another component (such as a circuit board or a chip) may be mounted on the solder ball 1230, such that the electrical signal transmitted to the first conductive pad 123 can further be transmitted to the another component through the solder ball 1230. The solder ball 1230 may be a tin ball.

In some embodiments, the first conductive structure 12 includes a conductive material, and the conductive material may be a conductive ink or a metal material. The conductive ink may include at least one element selected from a group consisting of silver, platinum, gold, copper, nickel, aluminum, and any combination thereof. The metal material may be silver, copper, or gold. The first conductive structure 12 may be formed by defining a hollow channel in the packaging body 11 and filling the conductive material into the hollow channel. In the embodiment, the conductive material is filled in the hollow channel by conductive ink spraying, copper electroplating, gold electroplating, or silver electroplating.

The photosensitive chip 20 is formed in the packaging body 11. The packaging body 11 improves the stability of the photosensitive chip 20. The photosensitive chip 20 includes a photosensitive area 21 and a non-photosensitive area 22 connected to each other. The photosensitive area 21 is exposed from the packaging body 11. The photosensitive area 21 can receive the optical signal formed by the external light beam passing through the lens assembly 2, and then convert the optical signal into the electrical signal. The non-photosensitive area 22 may surround the photosensitive area 21. The end of the second conductive channel 122 away from the third conductive pad 125 is connected to the non-photosensitive area 22. A connection pad 220 (such as an aluminum pad) may be provided on the non-photosensitive area 22. The end of the second conductive channel 122 away from the third conductive pad 125 may be connected to the aluminum pad of the non-photosensitive area 22.

The second conductive pad 124 and the third conductive pad 125 form a wiring layer through a Redistribution Layer (RDL) process. The second conductive pad 124 and the third conductive pad 125 can redistribute the connection pad 220 of the non-photosensitive area 22 to transmit the electrical signal of the photosensitive chip 20 to the substrate module 10. The specific positions of the second conductive pad 124 and the third conductive pad 125 on the packaging body 11 may be adjusted. As such, the electrical signal generated by the photosensitive chip 20 is transmitted to the first conductive pad 123 through the second conductive channel 122, the third conductive pad 125, the second conductive pad 124, and the first conductive channel 121, thereby achieving electrical connection between the photosensitive chip 20 and the substrate module 10.

In some embodiments, the packaging body 11 includes a first packaging block 111 and a second packaging block 112. The first packaging block 111 is located on the second surface 11B and at least adheres to the sidewall of the photosensitive chip 20. The first packaging block 111 may also adhere to a surface of the photosensitive chip 20 away from the photosensitive area 21. The second packaging block 112 is located on the first packaging block 111 and covers the non-photosensitive area 22 of the photosensitive chip 20. A surface of the first packaging block 111 away from the second packaging block 112 is the first surface 11A, and a surface of the second packaging block 112 away from the first packaging block 111 is the second surface 11B. At this time, the first conductive channel 121 is formed in the first packaging block 111 and the second packaging block 112, and the second conductive channel 122 is formed in the second packaging block 112. In some embodiments, the first packaging block 111 includes at least one of an epoxy resin and a phenolic resin, and the second packaging block 112 includes at least one of a polyimide adhesive and a Build-up Film. In other embodiments, the packaging body 11 may also be a one-piece structure.

The cover module 30 is located on the second surface 11B and covers the photosensitive chip 20. The cover module 30 can protect the photosensitive area 21 of the photosensitive chip 20, and reduce the damage to the photosensitive area 21 under an external force. In addition, the lens assembly 2 may be installed on the cover module 30. The surface of the cover module 30 is substantially flat, which is conducive to installing the lens assembly 2 on the surface of the cover module 30. The cover module 30 includes a cover plate body 31 and a second conductive structure 32 formed on the cover plate body 31. The cover plate body 31 may include glass or quartz. The cover plate body 31 includes a third surface 31A facing the second surface 11B and a fourth surface 31B opposite to the third surface 31A. The second conductive structure 32 includes a fourth conductive pad 321 exposed from the third surface 31A, and the fourth conductive pad 321 is connected to the second conductive pad 124 and the third conductive pad 125, respectively. The fourth conductive pad 321 forms a wiring layer through the RDL process, and the position of the fourth conductive pad 321 on the cover plate body 31 may be adjusted. The fourth conductive pad 321 is connected to the second conductive pad 124 and the third conductive pad 125, respectively, thereby achieving electrical connection among different wiring layers. In some embodiments, the fourth conductive pad 321 may be fixed to the second conductive pad 124 or the third conductive pad 125 by a solder paste. The second conductive structure 32 includes a conductive material, and the conductive material may be a conductive ink or a metal material. In the embodiment, the conductive material is formed by conductive ink spraying, copper electroplating, or silver electroplating.

Furthermore, the third surface 31A of the cover plate body 31 defines a groove 310. When viewed along a thickness direction of the cover plate body 31, the groove 310 at least partially overlaps with the photosensitive area 21. In some embodiments, the cover plate body 31 includes a base body 311 and an insulating protective layer 312 formed on a portion of the base body 311. The base body 311 may be a glass substrate or a quartz substrate. The groove 310 is located at the insulating protective layer 312 to expose a portion of the base body 311. That is, the bottom of the groove 310 is the base body 311. A surface of the insulating protective layer 312 away from the base body 311 is the third surface 31A. The fourth conductive pad 321 is provided on the insulating protective layer 312. The insulating protective layer 312 can provide insulation protection for the base body 311, and also provide a wiring pattern for forming the fourth conductive pad 321. At this time, the cover plate body 31 not only protects the photosensitive area 21 of the photosensitive chip 20, but also forms a filter at a portion of the cover plate body 31 by defining the grooves 310. The filter may absorb and removes a portion of the light within a certain wavelength while allowing the remaining portion of the light to pass through. In some embodiments, the cover module 30 may further include a first film layer 33 and a second film layer 34. The first film layer 33 is located on the portion of the base body 311 that is exposed from the groove 310. The second film layer 54 is located on a surface of the base body 311 away from the first film layer 33. When viewed along the above thickness direction, the first film layer 33 at least partially overlaps with the photosensitive area 21, and the second film layer 34 at least partially overlaps with the photosensitive area 21. As such, the first film layer 33, the second film layer 34, and a portion of the cover plate body 31 therebetween cooperatively constitute the filter. The first film layer 33 and the second film layer 34 may include a material depending on the function of the filter. For example, when the filter is an infrared cut-off filter that removes the light within the infrared wavelength, the first film layer 33 and the second film layer 34 may include a material selected from a group consisting of indium tin oxide (ITO), silicon nitride (Si₃N₄), titanium dioxide (TiO₂), and any combination thereof. The insulating protective layer 312 may be an insulating Build-up Film.

In the photoelectric packaging structure 100 of the present disclosure, the photosensitive chip 20 is embedded in the packaging body 11. The hollow channel is defined in the packaging body 11 and infilled with the conductive material to form the first conductive structure 12. The cover module 30 is formed on the packaging body 11 to achieve CIS system-level packaging. The first conductive structure 12 is connected to the non-photosensitive area 22 of the photosensitive chip 20, thereby achieving electrical connection between the photosensitive chip 20 and the substrate module 10. Furthermore, the second conductive structure 32 of the cover module 30 is connected to the second conductive pad 124 and the third conductive pad 125 of the first conductive structure 12, thereby forming a more complete wiring layer. The present disclosure eliminates the metal wires for electrically connecting the photosensitive chip 20 to the substrate module 10, so there is no need to reserve the space required for wire bonding tool, which is beneficial for reducing the lateral size of the photoelectric packaging structure 100 and conducive to the miniaturization of the photoelectric packaging structure 100. Moreover, compared with the existing circuit board wiring process, the cover module 30 of the present disclosure can also serve as a carrier for some wirings, there increasing the degree of freedom during the RDL process. The first conductive structure 12 is formed by defining the hollow channel in the packaging body 11 and filling the conductive material in the hollow channel, which is conducive to reducing the warpage and deformation of the carrier and improving the quality of the photoelectric packaging structure 100.

In some embodiments, the photoelectric packaging structure 100 further includes an electronic component 40, and the packaging body 11 further covers the electronic component 40. The first conductive structure 12 further includes a third conductive channel 126 and a fifth conductive pad 127. The third conductive channel 126 is formed in the packaging body 11, and the fifth conductive pad 127 is exposed from the second surface 11B. Two ends of the third conductive channel 126 are connected to the electronic component 40 and the fifth conductive pad 127, respectively. As such, the electrical signal generated by the photosensitive chip 20 is transmitted to the electronic component 40 through the second conductive channel 122, the third conductive pad 125, the fifth conductive pad 127, and the third conductive channel 126. The electronic component 40 may be a passive component or an active component. The passive component includes a resistor, a capacitor, etc. The active component includes a transistor, an integrated circuit, a picture tube, etc.

In some embodiments, the photoelectric packaging structure 100 further includes a sealing material 50 provided between the second surface 11B and the third surface 31A. The sealing material 50 surrounds the second conductive pad 124, the third conductive pad 125, the fourth conductive pad 321, and the fifth conductive pad 127. The sealing material 50 bonds the cover module 30 to the substrate module 10 to form a sealing cavity, thereby isolating external moisture or impurities and providing sealing protection for the photosensitive area 21. In the embodiment, the sealing material 50 may include a sealant.

A manufacturing method of the photoelectric packaging structure 100 in accordance with an embodiment. The method is provided by way of embodiments, as there are a variety of ways to carry out the method. The method can begin at step S1.

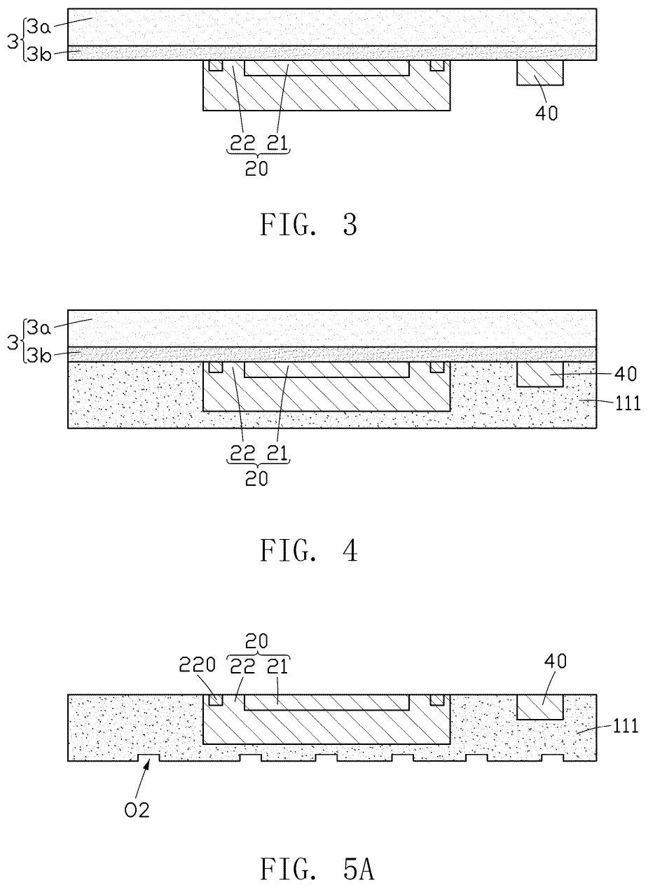

At step S1, referring to FIGS. 3 to 6, a packaging body 11 covers the photosensitive chip 20. The packaging body 11 includes a first surface 11A and a second surface 11B opposite to each other. A photosensitive area 21 of the photosensitive chip 20 is exposed from the second surface 11B.

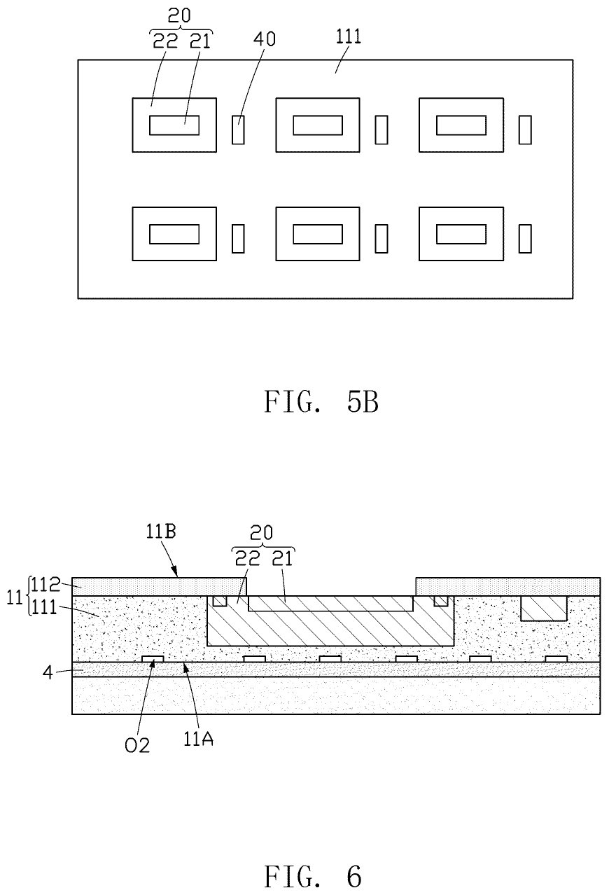

In some embodiments, the packaging body 11 may be obtained by first placing the photosensitive chip 20 on a first carrier board 3 (as shown in FIG. 3), allowing the photosensitive area 21 to face the first carrier board 3. Then, a first packaging block 111 is formed on the first carrier board 3 (as shown in FIG. 4), and the first packaging block 111 at least adheres to the sidewall of the photosensitive chip 20. The first carrier board 3 is removed (as shown in FIG. 5A), and then the first plastic packaging 111 with the photosensitive chip 20 is placed on a second carrier board 4, allowing the photosensitive area 21 to face away from the second carrier board 4. A second packaging block 112 is formed on the first packaging block 111 (as shown in FIG. 6), and the second packaging block 112 also covers the non-photosensitive area 22. At this time, as shown in FIG. 6, the first packaging block 111 and the second packaging block 112 cooperatively constitute the packaging body 11. A surface of the first packaging block 111 away from the second packaging block 112 is the first surface 11A, and a surface of the second packaging block 112 away from the first packaging block 111 is the second surface 11B. The first carrier board 3 and the second carrier board 4 have a supporting function at the corresponding steps to facilitate the forming of the first packaging block 111 and the second packaging block 112. In some embodiments, the first packaging block 111 and the second packaging block 112 may be formed through a molding process.

In some embodiments, as shown in FIGS. 3 and 4, the first carrier board 3 includes a carrier substrate 3a and a peelable layer 3b formed on the carrier substrate 3a, wherein the peelable layer 3b is located between the photosensitive chip 20 and the carrier substrate 3a. The carrier substrate 3a has a high mechanical strength, and the peelable layer 3b can decompose when heated, thereby facilitating the removal of the first carrier board 3 after forming the first packaging block 111. In some embodiments, the carrier substrate 3a may be a quartz substrate or a glass substrate. The peelable layer 3b may be made of a polymer such as LDF. The second carrier board 4 has a similar structure to the first carrier board 3.

In some embodiments, as shown in FIGS. 3 and 4, when the photosensitive chip 20 is placed on the first carrier board 3, the electronic component 40 may also be placed on the first carrier board 3, such that the electronic component 40 is formed in the first packaging block 111. Furthermore, referring to FIG. 5B, in some embodiments, multiple photosensitive chips 20 and multiple electronic components 40 may be placed on the first carrier board 3. The photosensitive chips 20 are arranged in a matrix on the first carrier board 3, and correspond one-to-one with the electronic components 40.

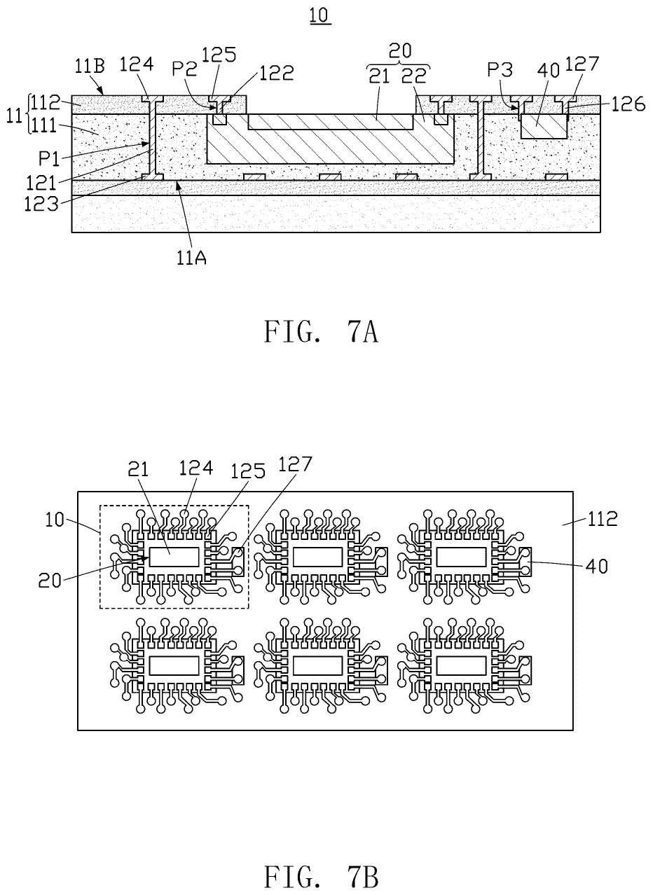

Step S2, referring to FIG. 7A, multiple first hollow channels P1 and multiple second hollow channels P2 are defined in the packaging body 11 by laser. The first hollow channel P1 extends from the second surface 11B to the first surface 11A, and the second hollow channel P2 extends from the second surface 11B to the non-photosensitive area 22.

In some embodiments, when the electronic component 40 is encapsulated in the packaging body 11, multiple third hollow channels P3 may also be defined in the packaging body 11 by laser, and the third hollow channel P3 extends from the second surface 11B to the electronic component 40. The ends of the multiple first hollow channels P1 facing the second carrier board 4 may cooperatively form a wiring pattern. The ends of the multiple first hollow channels P1 away from the second carrier board 4, the ends of the multiple second hollow channels P2 away from the second carrier board 4, and the ends of the multiple third hollow channels P3 away from the second carrier board 4 may cooperatively form a wiring pattern.

Step S3, referring to FIG. 7A, a conductive material is filled in the first hollow channel P1 and the second hollow channel P2 and solidified. Then, a substrate module 10 is obtained.

The first hollow channel P1 is filled with the conductive material and solidified to obtain the first conductive pad 123, the second conductive pad 124, and the first conductive channel 121. The first conductive pad 123 is exposed from the first surface 11A, and the second conductive pad 124 is exposed from the second surface 11B. Two ends of the first conductive channel 121 are connected to the first conductive pad 123 and the second conductive pad 124, respectively. The second hollow channel P2 is filled with the conductive material and solidified to obtain the second conductive channel 122 and the third conductive pad 125. The third conductive pad 125 is exposed from the second surface 11B, and two ends of the second conductive channel 122 are connected to the non-photosensitive area 22 and the third conductive pad 125, respectively.

In some embodiments, the conductive material may also be filled in the third hollow channel P3 and solidified to obtain a third conductive channel 126 and a fifth conductive pad 127. The fifth conductive pad 127 is exposed from the second surface 11B, and two ends of the third conductive channel 126 are connected to the electronic component 40 and the fifth conductive pad 127, respectively. The conductive material may be formed in the hollow channel by conductive ink printing or by electroplating. As shown in FIG. 7B, the second conductive pad 124, the third conductive pad 125, and the fifth conductive pad 127 cooperatively constitute a wiring layer through the RDL process, and the second conductive pad 124 and the third conductive pad 125 are connected to each other. Multiple third conductive pads 125 may surround the photosensitive area 21. The third conductive pad 125 is further connected to the fifth conductive pad 127.

In some embodiments, multiple first conductive pads 123 may also form a wiring layer through the RDL process. To facilitate the forming of the first conductive pads 123, a wiring pattern O2 can be defined at a surface of the first packaging block 111 away from the photosensitive area 21 before the first packaging block 111 with the photosensitive chip 20 is placed on the second carrier board 4 (as shown in FIG. 5A). As such, when the hollow channel is defined in the packaging body 11 by laser (as shown in FIG. 7A), the hollow channel communicates with a portion of the wiring pattern O2 to form the first hollow channel P1.

In some embodiments, as shown in FIG. 7B, multiple substrate modules 10 may be formed on the second carrier board 4 at once. As shown in FIG. 8, solder balls 1240 may be further placed on the second conductive pad 124, the third conductive pad 125, and the fifth conductive pad 127 of the substrate module 10. The solder ball 1240 may be a tin ball.

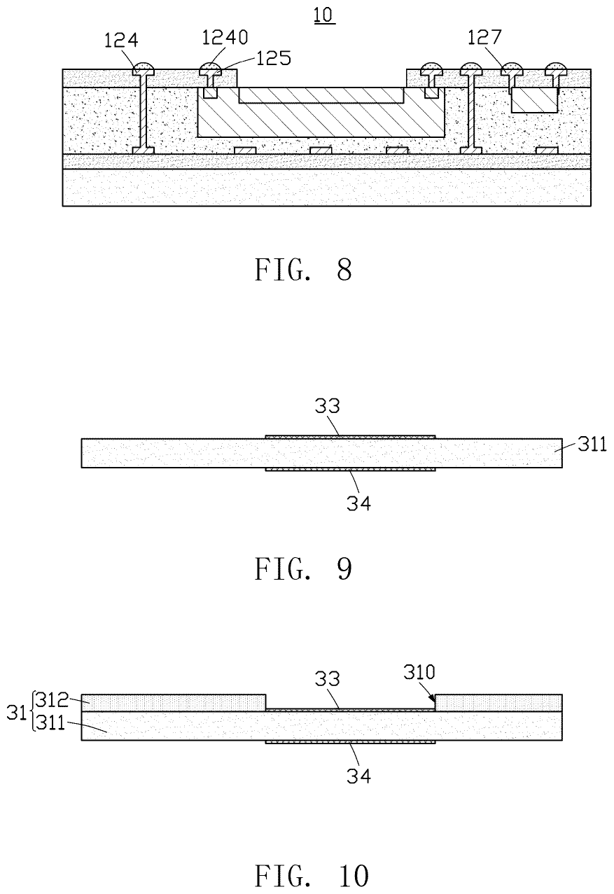

Step S4, referring to FIGS. 9 to 11A, a cover module 30 is manufactured.

The cover module 30 includes a cover plate body 31 and a second conductive structure 32. The cover plate body 31 may include glass or quartz, and the cover plate body 31 includes a third surface 31A and a fourth surface 31B opposite to each other. The second conductive structure 32 includes a fourth conductive pad 321 exposed from the third surface 31A.

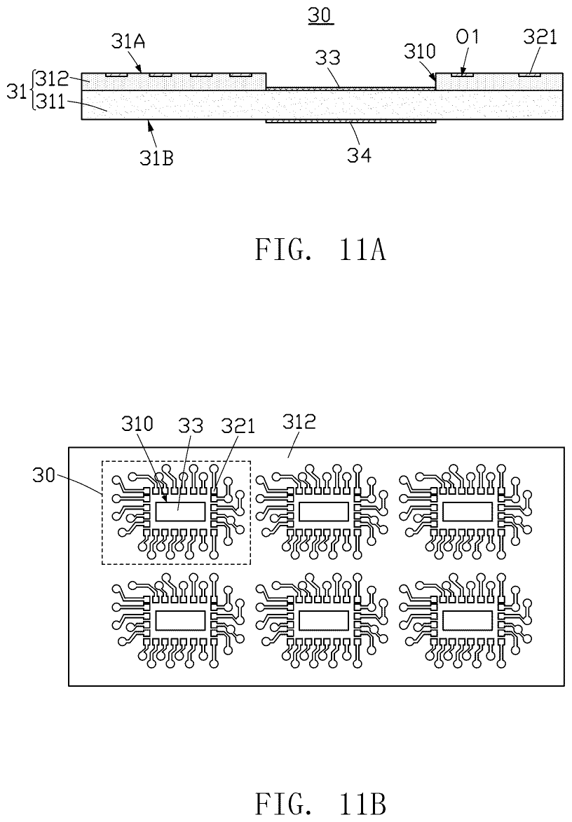

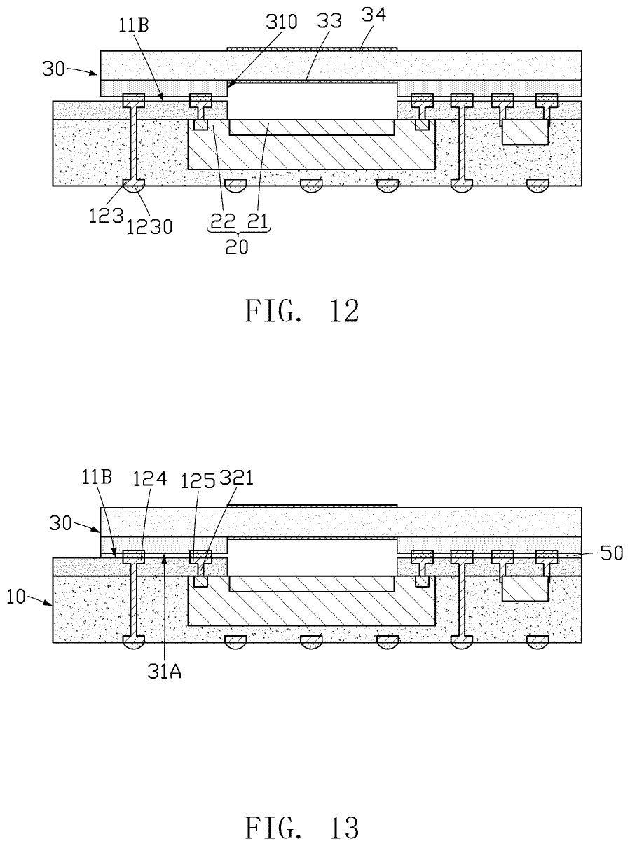

In some embodiments, the cover module 30 may be obtained by first providing an insulating protective layer 312 on a portion of the base body 311 (as shown in FIGS. 9 and 10), wherein the base body 311 may be a glass substrate or a quartz substrate. The insulating protective layer 312 has a groove 310 for exposing a portion of the base body 311. Then, a first patterned opening O1 is defined at the insulating protective layer 312, and a conductive material is filled in the first patterned opening O1 and solidified to obtain the fourth conductive pad 321 (as shown in FIG. 11A). The base body 311 and the insulating protective layer 312 cooperatively constitute the cover plate body 31, and a surface of the insulating protective layer 312 away from the substrate 311 is the third surface 31A. As shown in FIG. 11B, multiple fourth conductive pads 321 form a wiring layer through a RDL process, and the multiple fourth conductive pads 321 surround the groove 310. As shown in FIG. 11B, multiple cover modules 30 may be formed on the second carrier board 4 at once. In some embodiments, the insulating protective layer 312 may be an insulating Build-up Film.

Subsequently, a first film layer 33 may be formed on the portion of the base body 311 exposed from the groove 310. A second film layer 34 may be formed on a surface of the base body 311 away from the first film layer 33. It can be understood that the second film layer 34 may also be set before the forming of the first film layer 33. The second film layer 34 may also be formed simultaneously with the first film layer 33.

Step S5, referring to FIG. 12, the cover module 30 is formed on the second surface 11B, such that the fourth conductive pad 321 is connected to the second conductive pad 124 and the third conductive pad 125, respectively.

The fourth conductive pad 321 may be fixed to the second conductive pad 124 or the third conductive pad 125 by a solder ball 1240. When viewed along the thickness direction of the cover plate body 31, the groove 310 overlaps with the photosensitive area 21. When viewed along the thickness direction, the first film layer 33 overlaps with the photosensitive area 21, and the second film layer 34 overlaps with the photosensitive area 21.

In some embodiments, as shown in FIG. 12, a solder ball 1230 may be further formed on the first conductive pad 123. The solder ball 1230 may be a tin ball.

Step S6, referring to FIGS. 13 and 2, a sealing material 50 is formed between the second surface 11B and the third surface 31A, allowing the sealing material 50 to surround the second conductive pad 124, the third conductive pad 125, and the fourth conductive pad 321. At this time, the photoelectric packaging structure 100 is obtained.

In some embodiments, referring to FIGS. 11B and 13, the multiple cover modules 30 may be separated from each other, and the sealing material 50 is formed between the second surface 11B and the third surface 31A (as shown in FIG. 13). Then, the multiple substrate modules 10 may be separated from each other to obtain the photoelectric packaging structure 100 shown in FIG. 2.

### Second Embodiment

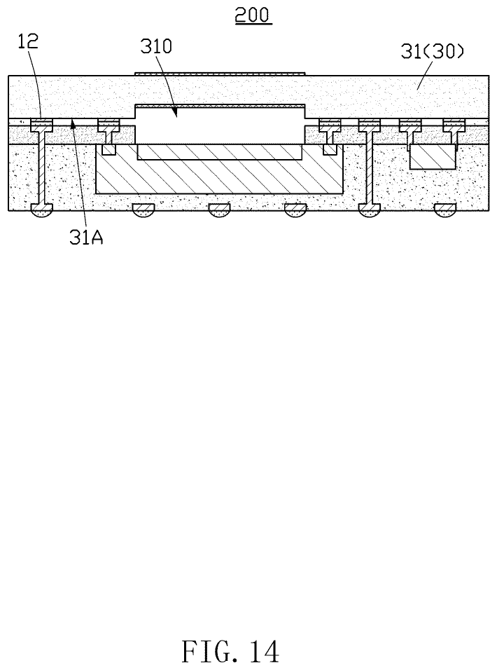

Referring to FIG. 14, a photoelectric packaging structure 200 is provided according to another embodiment of the present disclosure. The difference from the above photoelectric packaging structure 100 includes the structure of the cover module 30. Specifically, the insulating protective layer 312 is omitted, and the groove 310 is directly formed at the third surface 31A of the cover plate body 31. The forming of the groove 310 makes a portion of the cover plate body 31 to be thinned to form a filter. The first conductive structure 12 is directly formed on the third surface 31A.

A manufacturing method of the photoelectric packaging structure 200 is also provided according to another embodiment of the present disclosure. The difference from the above manufacturing method in the first embodiment includes the manufacturing steps of the cover module 30.

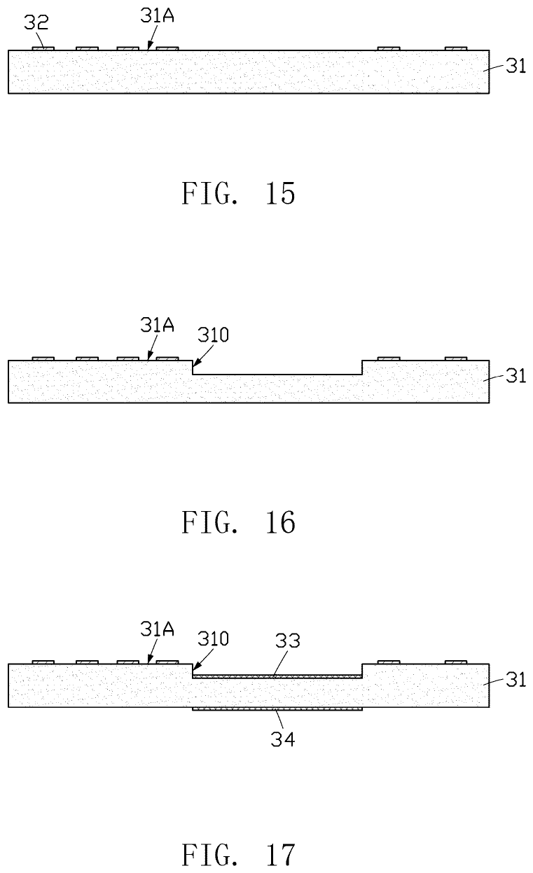

In the embodiment, the cover module 30 may be obtained, as shown in FIG. 15, by placing a mask (not shown) on the cover plate body 31, and the mask has a second patterned opening. Then, a conductive material is filled in the second patterned opening and solidified to obtain the second conductive structure 32. Finally, the mask is removed. The conductive material may be filled in the second patterned opening by conductive ink printing, copper electroplating, gold electroplating, or silver electroplating.

Then, as shown in FIG. 16, a groove 310 is defined at the third surface 31A of the cover plate body 31. As shown in FIG. 17, a first film layer 33 is formed on the bottom of the groove 310, and a second film layer 34 is formed on a surface of the cover plate body 31 away from the first film layer 33.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A photoelectric packaging structure comprising:
a substrate module comprising a packaging body and a first conductive structure, wherein the packaging body comprises a first surface and a second surface opposite to each other, the first conductive structure comprises a first conductive channel, a second conductive channel, a first conductive pad, a second conductive pad, and a third conductive pad, the first conductive channel and the second conductive channel are formed in the packaging body, the first conductive pad is exposed from the first surface, the second conductive pad and the third conductive pad are exposed from the second surface, and two ends of the first conductive channel are connected to the first conductive pad and the second conductive pad, respectively;
a photosensitive chip located in the packaging body, and comprising a photosensitive area and a non-photosensitive area connected to each other, wherein two ends of the second conductive channel are connected to the non-photosensitive area and the third conductive pad, respectively; and
a cover module located on the second surface, and comprising a cover plate body and a second conductive structure, wherein the cover plate body comprises a third surface facing the second surface, the second conductive structure comprises a fourth conductive pad exposed from the third surface, and the fourth conductive pad is connected to the second conductive pad and the third conductive pad.

2. The photoelectric packaging structure according to claim 1, wherein the third surface is provided with a groove, and the groove overlaps with the photosensitive area.

3. The photoelectric packaging structure according to claim 2, wherein the cover plate body comprises a base body and an insulating protective layer formed on a portion of the substrate, the fourth conductive pad is located on the insulating protective layer, the groove is defined in the protective layer, and a bottom of the groove is formed by the base body.

4. The photoelectric packaging structure according to claim 3, wherein the cover module further comprises a first film layer and a second film layer, the first film layer is located on the base body at the bottom of the groove, the second film layer is located on a surface of the base body from the first film layer, the first film layer overlaps with the photosensitive area, and the second film layer overlaps with the photosensitive area.

5. The photoelectric packaging structure according to claim 1, further comprising:
a sealing material formed between the second surface and the third surface, wherein the sealing material surrounds the second conductive pad, the third conductive pad, and the fourth conductive pad.

6. The photoelectric packaging structure according to claim 1, wherein the packaging body comprises a first packaging block and a second packaging block, the first packaging block is at least attached to a sidewall of the photosensitive chip, the second packaging block is located on the first packaging block and covers the non-photosensitive area, a surface of the first packaging block away from the second packaging block is the first surface, a surface of the second packaging block away from the first packaging block is the second surface;
the first conductive channel is formed in the first packaging block and the second packaging block, and the second conductive channel is formed in the second packaging block.

7. The photoelectric packaging structure according to claim 1, further comprising:
an electronic component located in the packaging body, wherein the first conductive structure further comprises a third conductive channel and a fifth conductive pad, the third conductive channel is located in the packaging body, the fifth conductive pad is exposed from the second surface, two ends of the third conductive channel are connected to the electronic component and the fifth conductive pad, respectively.

8. A manufacturing method of a photoelectric packaging structure, comprising:
forming a packaging body which covers a photosensitive chip, wherein the photosensitive chip comprises a photosensitive area and a non-photosensitive area connected to each other, the packaging body comprises a first surface and a second surface opposite to each other, and the photosensitive area is exposed from the second surface;
defining a first hollow channel and a second hollow channel in the packaging body by laser, wherein the first hollow channel extends from the second surface to the first surface, and the second hollow channel extends from the second surface to the non-photosensitive area;
filling a conductive material in the first hollow channel and solidifying the conductive material to obtain a first conductive pad, a second conductive pad, and a first conductive channel, wherein the first conductive pad is exposed from the first surface, the second conductive pad is exposed from the second surface, two ends of the first conductive channel are connected to the first conductive pad and the second conductive pad, respectively;
filling a conductive material in the second hollow channel and solidifying the conductive material to obtain a second conductive channel and a third conductive pad, wherein the third conductive pad is exposed from the second surface, and two ends of the second conductive channel are connected to the non-photosensitive area and the third conductive pad, respectively; and
forming a cover module on the second surface, wherein the cover module comprises a cover plate body and a second conductive structure, the cover plate body comprises a third surface facing the second surface, the second conductive structure comprises a fourth conductive pad exposed from the third surface, and the fourth conductive pad is connected to the second conductive pad and the third conductive pad.

9. The manufacturing method according to claim 8, wherein a manufacturing method of the cover module comprises:
forming an insulating protective layer on a portion of the base body, wherein the insulating protective layer defines a groove, and a bottom of the groove is formed by the base body;
defining a first patterned opening at the insulation protection layer; and
filling a conductive material in the first patterned opening and solidifying the conductive material to obtain the fourth conductive pad;
wherein the base body and the insulating protective layer cooperatively constitute the cover plate body, the fourth conductive pad is formed on the insulating protective layer, after the cover plate module is formed on the second surface, the groove overlaps with the photosensitive area.

10. The manufacturing method according to claim 9, wherein the manufacturing method of the cover module further comprises:
forming a first film layer on the base body at the bottom of the groove; and
forming a second film layer on a surface of the base body away from the first film layer;
wherein after forming the cover module on the second surface, the first film layer overlaps with the photosensitive area, and the second film layer overlaps with the photosensitive area.

11. The manufacturing method according to claim 8, wherein a manufacturing method of the cover module comprises:
forming a mask on the cover plate body, the mask having a second patterned opening;
filling a conductive material in the second patterned opening; and
removing the mask and solidifying the conductive material to obtain the second conductive structure.

12. The manufacturing method according to claim 11, wherein the manufacturing method of the cover module further comprises:
defining a groove on the third surface of the cover plate body;
forming a first film layer on a bottom of the groove; and
forming a second film layer on a surface of the cover plate body away from the first film layer;
wherein after forming the cover module on the second surface, the first film layer overlaps with the photosensitive area, and the second film layer overlaps with the photosensitive area.

13. The manufacturing method according to claim 9, wherein the conductive material is formed by conductive ink printing or metal electroplating.

14. The manufacturing method according to claim 8, wherein after forming the cover module on the second surface, the manufacturing method further comprises:
forming a sealing material between the second surface and the third surface, wherein the sealing material surrounds the second conductive pad, the third conductive pad, and the fourth conductive pad.

15. The manufacturing method according to claim 8, wherein forming the packaging body which covers the photosensitive chip comprises:
placing the photosensitive chip on a first carrier board, causing the photosensitive area to face the first carrier board;
forming a first packaging block on the carrier board, wherein the first packaging block is at least adhered to a sidewall of the photosensitive chip;
removing the first carrier board and placing the first packaging block with the photosensitive chip on a second carrier board, causing the photosensitive area to face away from the second carrier board; and
forming a second packaging block on the first packaging block, causing the second packaging block to further cover the non-photosensitive area, wherein the first packaging block and the second packaging block cooperatively constitute the packaging body, a surface of the first packaging block away from the second packaging block is the first surface, and a surface of the second packaging block away from the first packaging block is the second surface;
after forming the cover module on the second surface, the manufacturing method further comprises:
removing the second carrier board.

16. The manufacturing method according to claim 15, wherein after placing the photosensitive chip on the first carrier board, the manufacturing method further comprises:
placing an electronic components on the first carrier board;
wherein after forming the first packaging block on the first carrier board, the electronic component is located in the first packaging block, and the manufacturing method further comprises:
defining a third hollow channel in the packaging body, wherein the third hollow channel extends from the second surface to the electronic component; and
filling a conductive material in the third hollow channel and solidifying the conductive material to obtain a third conductive channel and a fifth conductive pad, wherein the fifth conductive pad is exposed from the second surface, and two ends of the third conductive channel are connected to the electronic component and the fifth conductive pad, respectively.

17. A camera module comprising:
a lens assembly; and
a photoelectric packaging structure according to claim 1, wherein the lens assembly is disposed on the cover module.
